(19) United States
(12) Patent Application Publication
(10) Pub. No.: US 2009/0042731 A1
(43) Pub. Date: Feb. 12, 2009

(54) METHOD OF PRODUCING OXIDE SUPERCONDUCTING WIRE

(75) Inventor: Shin-ichi Kobayashi, Osaka (JP)

Correspondence Address: DRINKER BIDDLE & REATH (DC), 1500 K STREET, N.W., SUITE 1100, WASHINGTON, DC, 20005-1209, US

(73) Assignee: Sumitomo Electric Industries, Ltd., Osaka-shi (JP)

(21) Appl. No.: 12/089,013

(22) PCT Filed: Jun. 15, 2007
(86) PCT No.: PCT/JP2007/062072

§ 371 Date: Apr. 4, 2008

(30) Foreign Application Priority Data
Aug. 4, 2006 (JP) 2006-212717

(51) Int. Cl. H01L 39/24

(52) U.S. Cl. 505/433; 29/599

(57) ABSTRACT

An object of the invention is to offer a method of producing an oxide superconducting wire that has a uniform performance throughout its length so that a wire can be obtained with just the intended length. The method of producing an oxide superconducting wire comprises a drawing step for drawing a wire having a configuration in which a precursor powder of a (Bi, Pb) 2223 superconducting body is covered with a metal sheath, a primary rolling step for rolling the wire having undergone the drawing step, a primary heat-treating step for heat-treating the wire having undergone the primary rolling step, a secondary rolling step for rolling the wire having undergone the primary heat-treating step, and a secondary heat-treating step for heat-treating the wire having undergone the secondary rolling step. Between the primary rolling step and the secondary heat-treating step, the method further comprises a step of sealing a sheath-lacking portion on the outer surface of the sheath by using a material consisting mainly of silver.

### TECHNICAL FIELD

The present invention relates to an oxide superconducting wire that is to be used in a superconductivity-applied apparatus, such as a superconducting cable, a superconducting coil, a superconducting transformer, and a superconducting power storage facility, and that contains a (Bi, Pb)₂Sr₂Ca₂Cu₃O_{10±δ} (hereinafter abbreviated as (Bi, Pb) 2223, and δ represents a number of about 0.1) phase, particularly a long oxide superconducting wire having uniform performance, and a production method thereof.

### BACKGROUND ART

An oxide superconducting wire that is composed mainly of the (Bi, Pb) 2223 phase and that is produced by the metal sheath method is a useful wire, because it not only has a high critical temperature but also shows a high critical current value even under a relatively simple cooling condition such as a liquid nitrogen temperature (see Nonpatent literature 1, for example). Consequently, when its performance (the critical current value) is further improved, the range of its practical application will be further broadened.

In addition, it is considered that by using the above-described (Bi, Pb) 2223 superconducting wire, the energy loss can be further decreased in comparison with the case where a conventional normal-conduction conductor is used. Therefore, researchers and engineers have been concurrently developing a superconducting cable, a superconducting coil, a superconducting transformer, a superconducting power storage facility, and other superconductivity-applied apparatuses all of which use the (Bi, Pb) 2223 superconducting wire as the conductor.

The critical current value of the (Bi, Pb) 2223 superconducting wire reaches a 120 A level at the liquid nitrogen temperature by sintering the superconducting wire in a pressurized atmosphere (see Patent literature 1 and Non-patent literature 1).
Patent literature 1: the published Japanese patent application Tokukai
Nonpatent literature 1: SEI Technical Review, March 2004, No. 164, pp. 36-42

### DISCLOSURE OF THE INVENTION

### Problem to be Solved by the Invention

The above-described technique has improved a basic performance (the critical current value). Nevertheless, it has been considerably difficult to achieve this performance uniformly throughout a long wire having a length as long as 100 m to 2 km. In a conventional method, a wire sometimes has a portion where the critical current value is low locally. In this case, the portion is removed (by cutting) to use the remaining portion. According to this method, first, a wire longer than the intended length is produced. Then, a portion from which the intended length can be obtained is selected for the use. Such a method reduces the yield. In view of the foregoing circumstances, an object of the present invention is to offer a method of producing an oxide superconducting wire that has no portion in which the performance is locally low so that a wire having just the intended length can be obtained.

### Means to Solve the Problem

The present invention offers a method of producing an oxide superconducting wire. The method is provided with the following steps:
(a) a drawing step for drawing a wire having a configuration in which a precursor powder of a (Bi, Pb) 2223 superconducting body is covered with a metal sheath,
(b) a primary rolling step for rolling the wire that has undergone the drawing step,
(c) a primary heat-treating step for heat-treating the wire that has undergone the primary rolling step,
(d) a secondary rolling step for rolling the wire that has undergone the primary heat-treating step, and
(e) a secondary heat-treating step for heat-treating the wire that has undergone the secondary rolling step.
   Between the primary rolling step and the secondary heat-treating step, the method is further provided with a step of sealing a sheath-lacking portion on the outer surface of the sheath by using a material consisting mainly of silver.

According to the present invention, it is desirable that the step of sealing the sheath-lacking portion by using a material consisting mainly of silver be performed between the secondary rolling step and the secondary heat-treating step.

Furthermore, in the present invention, it is desirable that the step of sealing the sheath-lacking portion be performed by using a method of applying a silver paste, a silver-sputtering method, or a covering method using silver foil.

In the present invention, it is desirable that the secondary heat-treating step be performed in a pressurized atmosphere.

### EFFECT OF THE INVENTION

The performing of the present invention can produce a long (Bi, Pb) 2223 oxide superconducting wire that has no portion in which the critical current value is locally low throughout its length.

### BRIEF DESCRIPTION OF THE DRAWING

FIG. 1 is a partly sectional perspective view schematically showing the structure of an oxide superconducting wire.

FIG. 2 is a flow chart showing a production process for the oxide superconducting wire of an embodiment of the present invention.

FIG. 3 is an illustration showing S1 step in FIG. 2.

FIG. 4 is an illustration showing S2 step in FIG. 2.

FIG. 5 is an illustration showing S3 step in FIG. 2.

FIG. 6 is an illustration showing S4 step in FIG. 2.

FIG. 7 is an illustration showing S5 step in FIG. 2.

### EXPLANATION OF THE SIGN

11: Oxide superconducting wire; 12: Oxide superconducting filament; 13: Sheath; 31: Precursor powder; 32: Metal tube; 41: Metal tube filled with a precursor powder; 42: Precursor powder; 43: Single-filament wire; 51: Single-filament wire; 52: Metal tube; 61: Multifilament wire; 62: Precursor powder; 63: Metal sheath; 64: Isotropic multifilament base wire; 71: Isotropic multifilament base wire; and 72: Tape-shaped precursor wire.

### BEST MODE FOR CARRYING OUT THE INVENTION

### Embodiment

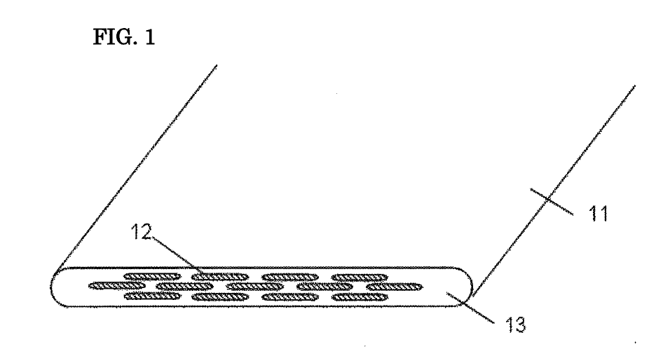

FIG. 1 is a partly sectional perspective view schematically showing the structure of an oxide superconducting wire. By referring to FIG. 1, an oxide superconducting wire having multiple filaments is explained, for example. An oxide superconducting wire 11 has a plurality of oxide superconducting filaments 12 extending in the direction of the length and a sheath 13 that covers them. It is desirable that the material of the individual oxide superconducting filaments 12 have a Bi—Pb—Sr—Ca—Cu—O-based composition. In particular, it is most desirable that the material contain a (Bi, Pb) 2223 phase, in which the atomic ratio of (Bi, Pb): Sr:Ca:Cu is approximately indicated as 2:2:2:3. The material of the sheath 13 is composed of metal, such as silver or a silver alloy.

Next, a method of producing the above-described oxide superconducting wire is explained.

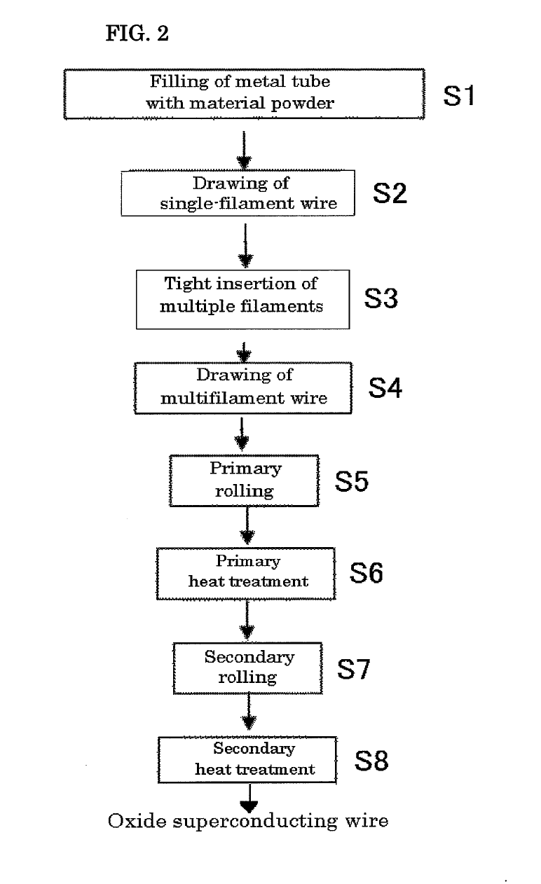

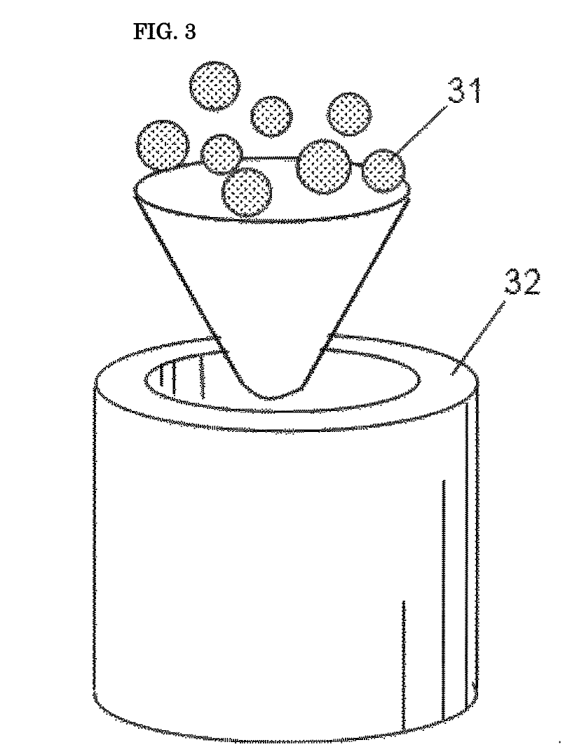

FIG. 2 is a flow chart showing a production process for the oxide superconducting wire of an embodiment of the present invention. FIGS. 3 to 7 are illustrations showing the individual steps in FIG. 2.

As can be seen from FIGS. 2 and 3, first, a metal tube 32 is filled with a precursor powder 31 of the oxide superconducting body (Step S1). The precursor powder 31 of the oxide superconducting body is made of, for example, a material having a (Bi, Pb)₂ Sr₂Ca₁Cu₂O_{8±δ} (hereinafter referred to as (Bi, Pb) 2212, and δ represents a number of about 0.1) phase as the main phase and containing a (Bi, Pb) 2223 phase, an oxide of alkaline earth such as (Ca, Sr)CuO₂, (Ca, Sr)₂CuO₃, and (Ca, Sr)₁₄Cu₂₄O₄₁, and an oxide of lead such as Ca₂PbO₄ and (Bi, Pb)₃Sr₂Ca₂Cu₁O_{z}. It is desirable to use silver or a silver alloy as the metal tube 32. The reason is to prevent the compositional deviation of the precursor powder due to the formation of a compound resulting from the reaction between the precursor powder and the metal tube.

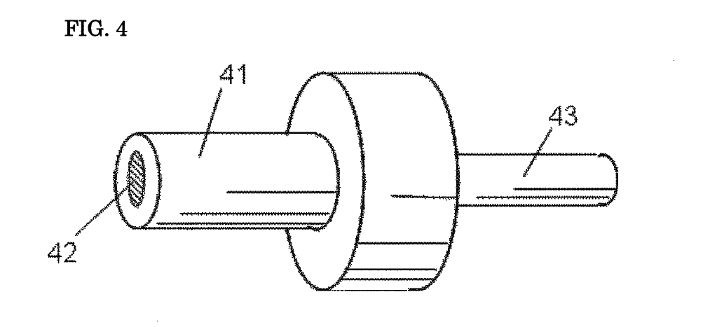

Next, as shown in FIGS. 2 and 4, a metal tube 41 filled with the foregoing precursor powder is processed by drawing until a desired diameter is achieved. This operation produces a single-filament wire 43 in which a precursor powder 42 as a filament material is covered with a metal such as silver (Step S2).

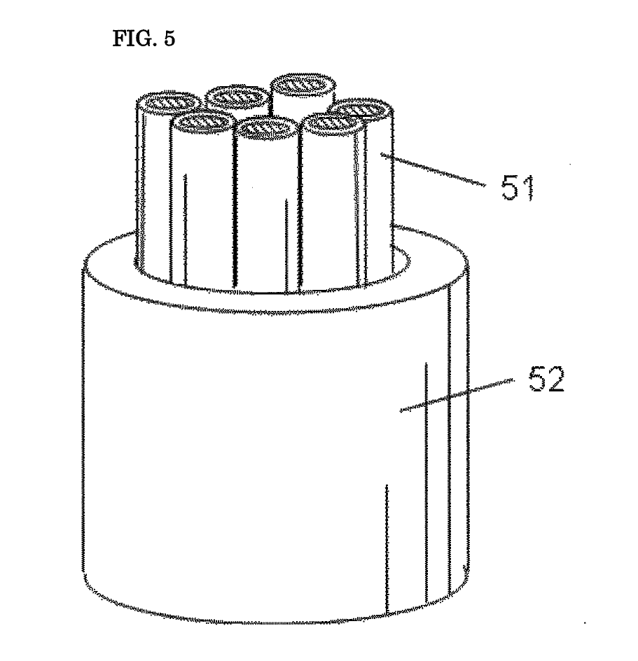

Next, as shown in FIGS. 2 and 5, a multitude of thus produced single-filament wires 51 are bundled together and are tightly inserted into a metal tube 52 made of, for example, silver (tight insertion of multiple filaments: Step S3). This operation produces a multifilament wire that has a multitude of precursor powders as the filament materials.

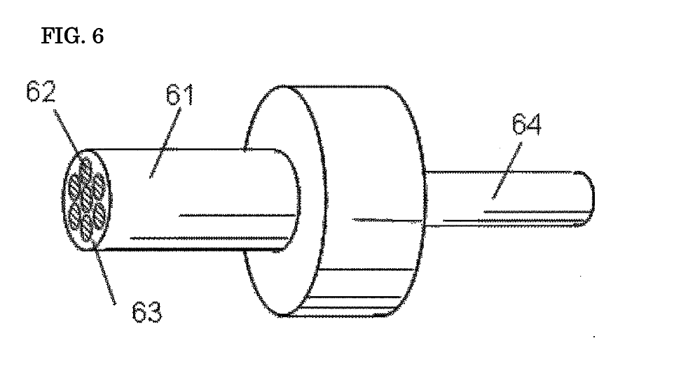

Next, as shown in FIGS. 2 and 6, a multifilament wire 61 is processed by drawing until a desired diameter is achieved. This operation produces an isotropic multifilament base wire 64 that has a structure in which precursor powders 62 are embedded in a metal sheath 63 and that has a circular or polygonal cross section (Step S4). Through this step, the isotropic multifilament base wire 64 having a configuration in which the precursor powders 62 of the oxide superconducting wire are covered with a metal is obtained.

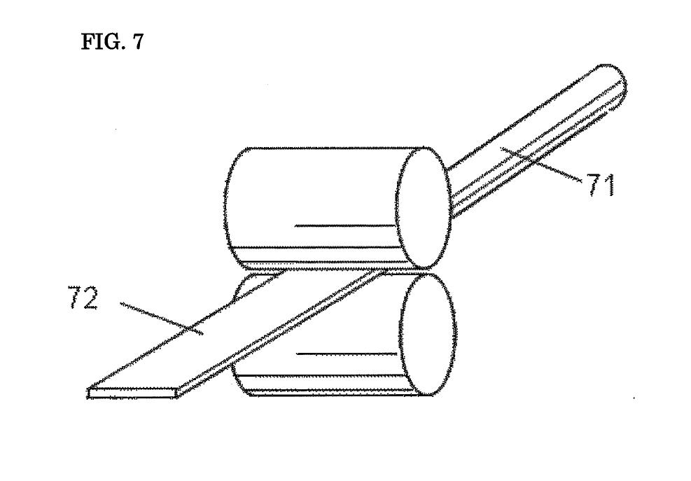

Next, as shown in FIGS. 2 and 7, a thus produced isotropic multifilament base wire 71 is rolled (a primary rolling: Step S5). Through this operation, a tape-shaped precursor wire 72 is obtained.

Next, the tape-shaped precursor wire is heat-treated (a primary heat treatment: Step S6). The heat treatment is performed, for example, at a temperature of about 830° C. under atmospheric pressure or in a pressurized atmosphere of at least 1 MPa and at most 50 MPa. The heat treatment produces an intended (Bi, Pb) 2223 superconducting phase out of the precursor powder.

After Step S6, the wire is rolled again (a secondary rolling: Step S7). Thus, by performing the secondary rolling, most of the voids (cavities) produced in the primary heat treatment are removed.

Subsequently, the wire is heat-treated at a temperature of, for example, about 830° C. (a secondary heat treatment: Step S8). In this case, also, the heat treatment is performed under atmospheric pressure or in a pressurized atmosphere. The above-described production steps produce the oxide superconducting wire shown in FIG. 1. Through the foregoing production process, an oxide superconducting wire is obtained.

Then, the obtained oxide superconducting wire is immersed in a coolant, such as liquid nitrogen, to measure the critical current value. Thus, its performance is confirmed.

In the above-described series of Steps, the wire sometimes develops on its surface a flaw, such as a pinhole and crack. Such a portion having a flaw lacks the silver used as the material of the sheath, thus producing a condition in which the inside of the filament communicates with the outside air. Through the portion that allows the communicating with the outside air, a gas or a liquid intrudes into the oxide superconducting wire. This intrusion produces a bulging phenomenon in the wire such that the shape of the wire is deformed.

The rolling step tends to produce a flaw such as a pinhole and crack. The flaw is caused by the fact that after the sheath becomes thin, when a portion is subjected to intense processing to the extent of exceeding its limit of ductility, the portion breaks. Consequently, it is recommended that after the primary rolling step, a sheath-lacking portion be sealed. In particular, it is effective to perform the sealing after the secondary rolling step. The reason is that the secondary rolling step has an increased tendency to produce a flaw such as a pinhole and crack. At the inside of the wire, through the primary heat treatment, the superconducting material grows in the filament portion to such an extent that it digs into the sheath, thereby producing an extremely thin portion in the sheath. When such a portion is rolled, a flaw tends to be produced, in particular. On the other hand, when a sealing material is applied before the secondary heat treatment, the sealing material reacts with the material of the sheath at the time of the secondary heat treatment, increasing the bonding strength between the two materials, so that the sealing effect is enhanced.

One of the bulging phenomena that deform the shape of the wire occurs when the wire is restored to room temperature after it is immersed in the coolant. This is caused by the fact that while the wire is immersed in the coolant, the coolant such as liquid nitrogen intrudes into the wire through the pin hole or the like, and the coolant having intruded gasifies during the temperature-rising period. In a portion where a path for the formed gas to escape is not properly secured, the gas expands in the wire and the wire bulges to such an extent that it deforms its outside shape. As described above, when the wire bulges to the extent of deforming its shape, the filament portion is broken, deteriorating the performance of the portion. As the wire that is free from the bulging phenomenon after the immersion in liquid nitrogen, a wire that is treated by sealing a sheath-lacking portion on its surface is suitable.

In addition, when a sheath-lacking portion exists, another bulging phenomenon will occur at the time the secondary heat treatment is performed in a pressurized atmosphere. When the wire is exposed in a pressurized atmosphere, the outside air intrudes into the wire through the pin hole or the like. In this case, the gas accumulated in the wire has the same pressure as that of the outside air. For example, when the outside air has a pressure of 30 MPa, the gas accumulated in the wire has a pressure of 30 MPa. When the outside air pressure is maintained at 30 MPa, equilibrium is maintained, so that the inside gas does not expand. However, after the heat treatment is completed, at the time the outside air pressure is reduced, if a path for the gas accumulated in the wire to escape is not secured, the gas in the wire expands at the place to cause a bulging phenomenon in the wire.

Furthermore, in addition to the causing of the bulging phenomenon, the sheath-lacking portion is difficult to attain the effect of the pressurized heat treatment. The purpose of the pressurized heat treatment is to increase the density of the filament. In other words, the purpose is to achieve better contact between the superconducting crystals in the filament by crushing, with an external pressure, the voids (cavities) remaining in the filament even after the secondary rolling. However, at a portion where the outside air has intruded, the pressure becomes the same as the outside air pressure, reaching equilibrium. In this case, no voids are compressed. More specifically, the superconducting crystals are not brought into intimate contact with one another, decreasing the performance at the portion.

Not only to prevent the above-described bulging phenomenon but also to obtain the effect of the pressurized heat treatment, it is desirable to heat-treat a wire treated by sealing a sheath-lacking portion on its surface before the secondary heat treatment. The most effective sealing timing is between the secondary rolling and the secondary heat treatment so that the sheath-lacking portion can be finally sealed.

As the material to seal the sheath-lacking portion, it is desirable to use a material consisting mainly of silver. The reason is that because the sealing operation is performed before the secondary heat treatment as described above, the sealing material also undergoes the heat treatment. The sealing material sometimes comes into contact with the filament portion. When a material other than silver is brought into contact with the filament portion as the sealing material, the sealing material reacts with the filament portion at the time of the heat treatment. As a result, such a phenomenon that an intended superconducting phase is not formed will occur. Therefore, as the sealing material, it is desirable to use a material consisting mainly of silver, which has low reactivity with the filament portion.

The method of sealing the sheath-lacking portion is not particularly limited providing that the method can fill the sheath-lacking portion without leaving any gap. More specifically, it is desirable to adopt a method of applying a silver paste, a method of vapor-depositing silver with a sputtering technique, a covering method using silver foil, and so on.

### Example

The present invention is explained more specifically below based on an example.

Material powders (Bi₂O₃, PbO, SrCO₃, CaCO₃, and CuO) are mixed with a ratio of Bi:Pb:Sr:Ca:Cu=1.8:0.3:1.9:2.0:3.0. The mixed powder successively undergoes a heat treatment at 700° C. for eight hours in the atmosphere, pulverization, a heat treatment at 800° C. for 10 hours, pulverization, a heat treatment at 820° C. for four hours, and pulverization. Thus, a precursor power is obtained. Alternatively, a precursor power can also be produced by using the following spraying pyrolysis technique: First, a nitric acid solution in which the five types of material powders are dissolved is sprayed into a heated furnace. Then, the water in the particles of the metal nitrate solution evaporates, instantaneously causing the thermal cracking of the nitrate, reactions between the metal oxides, and synthesis of them. The thus produced precursor powder is a powder composed mainly of a Bi2212 phase. In addition, a part of the mixed material powder is heat-treated by altering the treating condition to obtain a precursor powder in which a (Bi, Pb) 2212 phase is the main phase.

The precursor powder produced as described above is charged into a silver tube having an outer diameter of 25 mm and an inner diameter of 22 mm. The tube is drawn until the diameter becomes 2.4 mm to produce a single-filament wire. Fifty-five of the single-filament wires are bundled together to be inserted into a silver tube having an outer diameter of 25 mm and an inner diameter of 22 mm. The tube is drawn until the diameter becomes 1.5 mm to obtain a multifilament (55-filament) wire.

After the heat treatment as described above, the multifilament wire is processed by rolling to obtain a tape-shaped wire having a thickness of 0.25 mm. The obtained tape-shaped wire undergoes the primary heat treatment at 830° C. for 30 to 50 hours in an atmosphere at a total pressure of one atmosphere (0.1 MPa) and an oxygen partial pressure of 8 kPa.

The tape-shaped wire having undergone the primary heat treatment was rolled again so that the wire could have a thickness of 0.23 mm. At this stage, the wire had a length of 600 m. The wire was divided into six wires, each having a length of 100 m. The individual wires were designated by Wire 1 to 6. At this stage, sheath-lacking portions of the individual wires were visually examined. The results of the examination are shown in Table I. In accordance with the below-described measuring position of the critical current value, the presence of a sheath-lacking portion is shown for every 4-m section. For example, in the case of Wire 1, a sheath-lacking portion was found at a 5.5-m portion. This is indicated by “present” in the 4-8-m section. Wire 1 had four sheath-lacking portions. Wires 2 to 6 were also similarly examined.

TABLE I

| | | | | | | | Wire 4 | | Wire 5 | | Wire 6 | |
|---|---|---|---|---|---|---|---|---|---|---|---|---|
| | Wire 1 | | Wire 2 | | Wire 3 | | (Comparative | | (Comparative | | (Comparative | |
| | (Example) | | (Example) | | (Example) | | example) | | example) | | example) | |
| Position | Sheath- | | Sheath- | | Sheath- | | Sheath- | | Sheath- | | Sheath- | |
| of wire | lacking | | lacking | | lacking | | lacking | | lacking | | lacking | |
| (m) | portion | Ic (A) | portion | Ic (A) | portion | Ic (A) | portion | Ic (A) | portion | Ic (A) | portion | Ic (A) |
| 0-4 | | Good | | Good | Present | Good | | Good | | Good | | Good |
| 4-8 | Present | Good | | Good | | Good | | Good | | Good | Present | 100 |
| 8-12 | | Good | | Good | | Good | Present | Good | | Good | | Good |
| 12-16 | | Good | Present | Good | | Good | | Good | Present | 90 | | Good |
| 16-20 | | Good | | Good | | Good | | Good | | Good | | Good |
| 20-24 | | Good | | Good | Present | Good | | Good | Present | 100 | | Good |
| 24-28 | | Good | | Good | | Good | | Good | | Good | | Good |
| 28-32 | | Good | | Good | | Good | | Good | | Good | | Good |
| 32-36 | | Good | | Good | | Good | Present | 120 | | Good | | Good |
| 36-40 | Present | Good | | Good | Present | Good | | Good | | Good | | Good |
| 40-44 | | Good | | Good | | Good | | Good | Present | 110 | | Good |
| 44-48 | | Good | | Good | | Good | | Good | | Good | | Good |
| 48-52 | | Good | Present | Good | | Good | Present | Good | | Good | | Good |
| 52-56 | | Good | | Good | | Good | | Good | | Good | | Good |
| 56-60 | | Good | | Good | | Good | | Good | | Good | | Good |
| 60-64 | Present | Good | | Good | | Good | | Good | | Good | | Good |
| 64-68 | | Good | | Good | Present | Good | | Good | | Good | Present | 120 |
| 68-72 | | Good | | Good | | Good | | Good | Present | 120 | | Good |
| 72-76 | | Good | | Good | | Good | | Good | | Good | | Good |
| 76-80 | | Good | Present | Good | | Good | | Good | | Good | | Good |
| 80-84 | | Good | | Good | | Good | | Good | | Good | | Good |
| 84-88 | | Good | | Good | | Good | Present | 80 | | Good | Present | 80 |
| 88-92 | Present | Good | | Good | | Good | | Good | | Good | | Good |
| 92-96 | | Good | | Good | | Good | | Good | Present | 110 | | Good |
| 96-100 | | Good | | Good | Present | Good | | Good | | Good | | Good |

Next, for Wire 1, a silver paste was applied to the sheath-lacking portion to seal it (Example). For Wire 2, silver particles were vapor-deposited to the sheath-lacking portion with a sputtering technique to seal it (Example). For Wire 3, silver foil (thickness: 100 μm) was wound onto the sheath-lacking portion to seal it (Example). For Wire 4, no treatment was performed (Comparative example). For Wire 5, copper foil (thickness: 100 μm) was wound onto the sheath-lacking portion to seal it (Comparative example). For Wire 6, aluminum foil (thickness: 80 μm) was wound onto the sheath-lacking portion to seal it (Comparative example). Subsequently, the individual Wires underwent the secondary heat treatment at 830° C. for 50 to 100 hours in a pressurized atmosphere at a total pressure of 30 MPa including an oxygen partial pressure of 8 kPa.

The produced Wires were subjected to measurement of the critical current value (Ic). For individual Wires, every 4-m section was immersed in liquid nitrogen to perform the measurement for the immersed section. The critical current value was measured through the following method: First, a current-voltage curve was obtained using the four-terminal method. Then, by referring to the curve, a current needed to produce a voltage of 1×10⁻⁶ V per centimeter of wire (400 μV for 4 m) was obtained and defined as the critical current value.

The measured results of the critical current value are shown in Table I. In the table, “good” shows that the critical current value falls in the range of 150 to 160 A and consequently the section is judged as good. On the other hand, the section described in numerical value has a critical current value less than 150 A. For all the Wires, the section having no sheath-lacking portion shows a critical current value of 150 A or more. In the case of Wires 1 to 3, which are treated by using a technique of the present invention, even the sheath-lacking portion shows a critical current value of 150 A or more. On the other hand, for Wire 4, to which no treatment is performed, although some sections having a sheath-lacking portion show 150 A or more, other sections having a sheath-lacking portion show as low as 80 A and 120 A. For Wires 5 and 6, which are treated by sealing the sheath-lacking portion with copper foil and aluminum foil, respectively, the performance is decreased at the sheath-lacking portion in both Wires. This is because the filament reacts with the copper foil and aluminum foil, preventing the superconducting phase from growing.

The individual Wires were subjected to the counting of the number of bulges both after the secondary heat treatment and after the measurement of the critical current value. The results are shown in Table II. For both of Examples and Comparative examples, Wires treated by sealing the sheath-lacking portion using some method show that the number of bulges is “zero” both after the secondary heat treatment and after the measurement of the critical current value. On the other hand, Wire 4, to which no treatment is performed, shows that one bulge is produced at the time of the heat treatment and two bulges are produced due to the intrusion of liquid nitrogen at the time of the measurement. This result demonstrates that the sealing of the sheath-lacking portion is effective in preventing the bulging phenomenon.

TABLE II

| | | | | Wire 4 | Wire 5 | Wire 6 |
|---|---|---|---|---|---|---|
| | Wire 1 | Wire 2 | Wire 3 | (Comparative | (Comparative | (Comparative |
| | (Example) | (Example) | (Example) | example) | example) | example) |
| Number of bulges | 0 | 0 | 0 | 1 | 0 | 0 |
| after secondary heat | | | | | | |
| treatment | | | | | | |
| Number of bulges | 0 | 0 | 0 | 2 | 0 | 0 |
| after measurement | | | | | | |

It is to be considered that the above-disclosed embodiments and examples are illustrative and not restrictive in all respects. The scope of the present invention is shown by the scope of the appended claims, not by the above-described embodiments and examples. Accordingly, the present invention is intended to cover all revisions and modifications included within the meaning and scope equivalent to the scope of the claims.

1. A method of producing an oxide superconducting wire, the method comprising:
(a) a drawing step for drawing a wire having a configuration in which a precursor powder of a (Bi, Pb) 2223 superconducting body is covered with a metal sheath;
(b) a primary rolling step for rolling the wire that has undergone the drawing step;
(c) a primary heat-treating step for heat-treating the wire that has undergone the primary rolling step;
(d) a secondary rolling step for rolling the wire that has undergone the primary heat-treating step; and
(e) a secondary heat-treating step for heat-treating the wire that has undergone the secondary rolling step;
between the primary rolling step and the secondary heat-treating step, the method further comprising a step of sealing a sheath-lacking portion on the outer surface of the sheath by using a material consisting mainly of silver.

2. The method of producing an oxide superconducting wire as defined by claim 1, wherein the step of sealing the sheath-lacking portion by using a material consisting mainly of silver is performed between the secondary rolling step and the secondary heat-treating step.

3. The method of producing an oxide superconducting wire as defined by claim 1, wherein the step of sealing the sheath-lacking portion is performed by using a method of applying a silver paste, a silver-sputtering method, or a covering method using silver foil.

4. The method of producing an oxide superconducting wire as defined by claim 1, wherein the secondary heat-treating step is performed in a pressurized atmosphere.
